(19) United States
(12) Patent Application Publication
(10) Pub. No.: US 2026/0370980 A1
(43) Pub. Date: Nov. 19, 2026

(54) PHOTOELECTRIC CONVERSION DEVICE

(71) Applicant: CANON KABUSHIKI KAISHA, Tokyo (JP)

(72) Inventor: WATARU ENDO, Tokyo (JP)

(21) Appl. No.: 19/677,474

(22) Filed: May 14, 2026

(30) Foreign Application Priority Data
May 19, 2025 (JP) 2025-083225
Mar. 10, 2026 (JP) 2026-037722

(51) Int. Cl. H04N 25/773; H04N 7/18; H04N 25/79; H10F 39/00

(52) U.S. Cl. CPC H04N 25/773; H04N 7/183; H04N 25/79; H10F 39/809

(57) ABSTRACT

A photoelectric conversion device includes a pixel including a photoelectric conversion element and a count processing unit configured to perform count processing on a signal output from the photoelectric conversion element, a first substrate on which the photoelectric conversion element is formed, and a second substrate on which the count processing unit is formed, and which is stacked on the first substrate. The count processing unit includes a plurality of first conductivity type transistors and a plurality of second conductivity type transistors. In the second substrate, the count processing unit is divided into a first region including an equal number of the first conductivity type transistors and the second conductivity type transistors, and a second region including either the first conductivity type transistors or the second conductivity type transistors.

### BACKGROUND

### Field of the Technology

The present disclosure relates to a photoelectric conversion device.

### Description of the Related Art

A photoelectric conversion device capable of detecting a single photon using an avalanche photodiode (APD) is known. The photoelectric conversion device disclosed in Japanese Patent Laid-Open No. 2022-112735 includes a plurality of pixels each having a count processing unit that counts a signal obtained by avalanche multiplication of an APD.

In the pixel, a circuit area including the count processing unit is increased.

### SUMMARY

According to one aspect of the present specification, there is provided a photoelectric conversion device that includes a pixel including a photoelectric conversion element and a count processing unit configured to perform count processing on a signal output from the photoelectric conversion element, a first substrate on which the photoelectric conversion element is formed, and a second substrate on which the count processing unit is formed so as to overlap at least a part of the photoelectric conversion element in a plan view, and which is stacked on the first substrate, wherein the count processing unit includes a plurality of first conductivity type transistors and a plurality of second conductivity type transistors, and wherein, in the second substrate, the count processing unit is divided into a first region including an equal number of the first conductivity type transistors and the second conductivity type transistors, and a second region including either the first conductivity type transistors or the second conductivity type transistors.

Features of the present disclosure will become apparent from the following description of embodiments with reference to the attached drawings. The following description of embodiments is described by way of example.

### BRIEF DESCRIPTION OF THE DRAWINGS

FIG. 1 is an exploded perspective view of a photoelectric conversion device according to a first embodiment.

FIG. 2 is a block diagram of a sensor substrate according to the first embodiment.

FIG. 3 is a block diagram of a circuit substrate according to the first embodiment.

FIG. 4 is a block diagram of a pixel according to the first embodiment.

FIG. 5 is a timing chart illustrating the operation of the pixel according to the first embodiment.

FIG. 6 is a circuit diagram of a count processing unit according to the first embodiment.

FIG. 7 is a circuit diagram of a flip-flop according to the first embodiment.

FIG. 8 is a plan view of a count processing unit according to a comparative example.

FIG. 9 is a plan view of a count processing unit according to the first embodiment.

FIG. 10 is a plan view of a count processing unit according to a second embodiment.

FIG. 11 is a circuit diagram of a selection circuit according to a third embodiment.

FIG. 12 is a plan view of a count processing unit and a selection circuit according to the third embodiment.

FIG. 13 is a plan view of an interconnect layer of a count processing unit and a selection circuit according to the third embodiment.

FIG. 14 is an exploded perspective view of a photoelectric conversion device according to a fourth embodiment.

FIG. 15 is a block diagram of a pixel according to the fourth embodiment.

FIG. 16 is a block diagram of a sensor substrate according to a fifth embodiment.

FIG. 17 is a block diagram of a circuit substrate according to the fifth embodiment.

FIG. 18 is a block diagram of a pixel according to the fifth embodiment.

FIG. 19 is a circuit diagram of a count processing unit according to the fifth embodiment.

FIG. 20 is a block diagram of an equipment according to a sixth embodiment.

FIGS. 21A and 21B are block diagrams of an equipment according to a seventh embodiment.

### DESCRIPTION OF THE EMBODIMENTS

The following embodiments are intended to embody the technical idea of the present disclosure, and do not limit the present disclosure. The sizes and positional relationships of members illustrated in the drawings may be exaggerated for clarity of description. In the following description, the same components are denoted by the same reference numerals, and the description thereof may be omitted.

The plan view refers to a view from a direction perpendicular to a light incident surface of a semiconductor layer. When the light incident surface of the semiconductor layer is a rough surface as viewed microscopically, the plan view is defined with reference to the light incident surface of the semiconductor layer as viewed macroscopically.

In the following description, a fixed potential is applied to an anode of an avalanche photodiode (APD), and signal charges are extracted from a cathode side. Here, the semiconductor region having the charge of the same polarity as the signal charge as the majority carrier is referred to as a first conductivity type (N-type) semiconductor region, and the semiconductor region having the charge of a polarity different from the signal charge as the majority carrier is referred to as a second conductivity type (P-type) semiconductor region. A fixed potential may be applied to the cathode of the APD, and the signal charge may be extracted from the anode side. In this case, the semiconductor region having the charge of the same polarity as the signal charge as the majority carrier is the semiconductor region of the first conductivity type (P-type), and the semiconductor region having the charge of the polarity different from the signal charge as the majority carrier is the semiconductor region of the second conductivity type (N-type). Although a case where one node of the APD is set to a fixed potential will be described below, the potentials of both nodes may vary.

An N-type MOS (N-channel Metal-Oxide-Semiconductor) transistor is a first conductivity type transistor, a P-type MOS (P-channel Metal-Oxide-Semiconductor) transistor is described as a second conductivity type transistor. However, the present disclosure is not limited to this example. When it is not necessary to distinguish between the N-type transistor and the P-type transistor, the transistors may be simply referred to as the transistors.

Further, the term "impurity concentration" may mean an effective impurity concentration which is a difference between an N-type dopant impurity concentration and a P-type dopant impurity concentration. That is, the "impurity concentration" refers to the net doping concentration. A region where the P-type dopant impurity concentration is higher than the N-type dopant impurity concentration is a P-type semiconductor region. Conversely, a region where the N-type dopant impurity concentration is higher than the P-type dopant impurity concentration is an N-type semiconductor region.

In the following embodiments, connection between elements of a circuit may be described. In this case, even when another element is interposed between the interest elements, the interest elements are connected to each other unless otherwise specified. For example, an element A is connected to one node of a capacitor C having a plurality of nodes, and an element B is connected to the other node. Even in such a case, the element A and the element B are connected to each other unless otherwise specified.

### First Embodiment

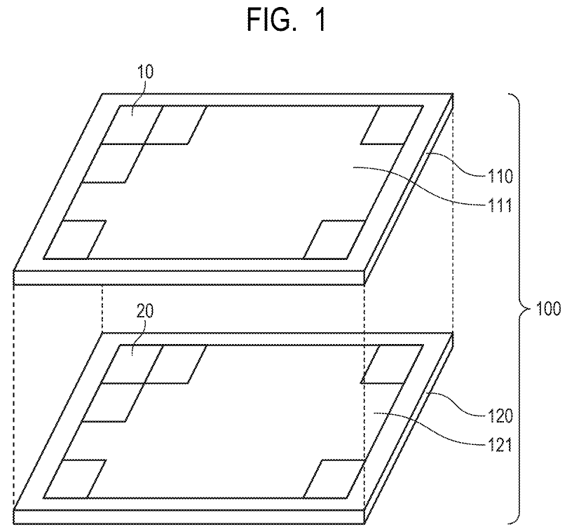

FIG. 1 is an exploded perspective view of a stacked photoelectric conversion device 100 according to the present embodiment. The photoelectric conversion device 100 includes a sensor substrate (first substrate) 110 and a circuit substrate (second substrate) 120 that are stacked and electrically connected to each other. The sensor substrate 110 has a pixel region 111, and the circuit substrate 120 has a circuit region 121. The photoelectric conversion device 100 includes a plurality of pixels, and each pixel includes a photoelectric conversion unit 10 and a signal processing unit (processing circuit) 20. The photoelectric conversion unit 10 is disposed in the pixel region 111, and the signal processing unit 20 is disposed in the circuit region 121.

The sensor substrate 110 has a first semiconductor layer including the photoelectric conversion unit 10 and a first interconnect structure including interconnects. The circuit substrate 120 has a second semiconductor layer including the signal processing unit 20, and a second interconnect structure including interconnects. In the photoelectric conversion device 100, the second semiconductor layer, the second interconnect structure, the first interconnect structure, and the first semiconductor layer are stacked in this order. The photoelectric conversion device 100 is a back-illuminated type in which light is incident from the second surface of the first semiconductor layer and the circuit substrate 120 is provided on the first surface of the first semiconductor layer.

Hereinafter, the sensor substrate 110 and the circuit substrate 120 will be described as diced chips but are not limited to chips. For example, each substrate may be a wafer. In addition, each substrate may be diced after being stacked in a wafer state, or each chip may be stacked and bonded after being converted into a chip from a wafer state.

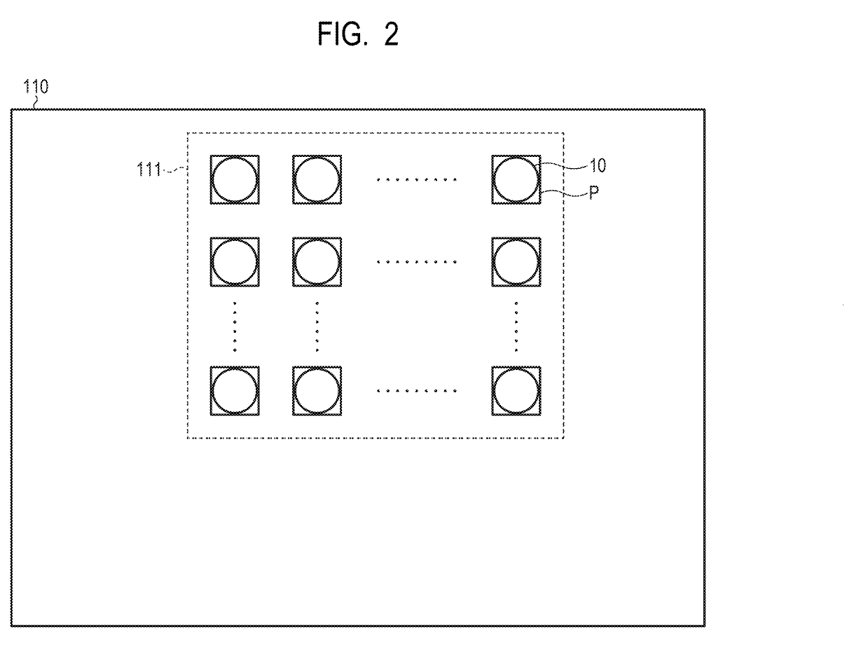

FIG. 2 is a block diagram of the sensor substrate 110 according to the present embodiment. In the pixel region 111 of the sensor substrate 110, the photoelectric conversion units 10 of the pixels P are arranged in a two-dimensional array in the plan view. The photoelectric conversion units 10 in the pixel region 111 may be arranged in a one-dimensional array.

Although the pixel P is typically used to generate an image, the pixel P may not necessarily generate an image when used in Time of Flight (TOF). That is, the pixel P may measure the time at which light reaches the pixel P and the amount of light.

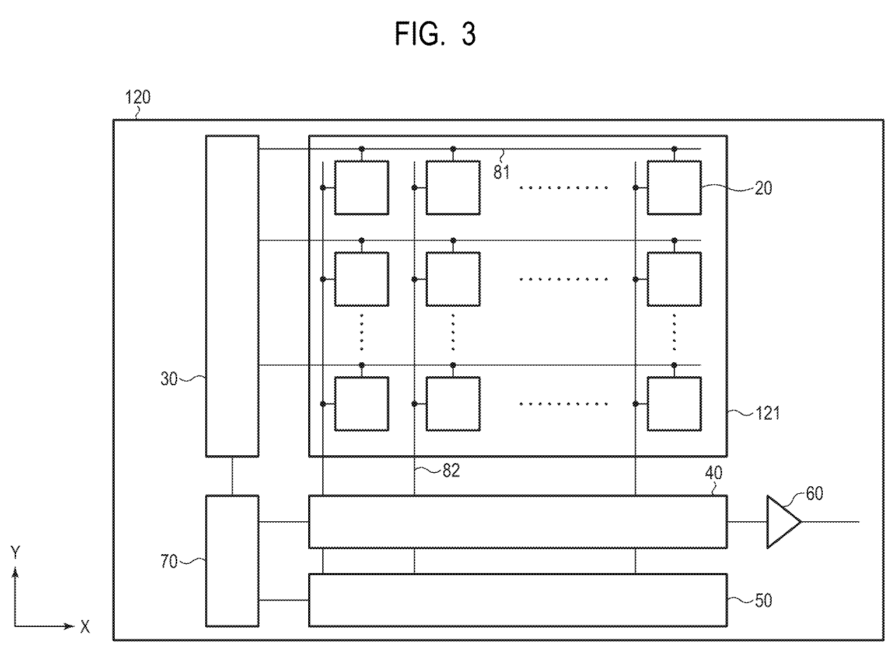

FIG. 3 is a block diagram of the circuit substrate 120 according to the present embodiment. In the circuit region 121 of the circuit substrate 120, the signal processing units 20 are arranged in a two-dimensional array in the plan view. The pixel region 111 and the circuit region 121 overlap in the plan view, and at least a part of the photoelectric conversion unit 10 and the signal processing unit 20 overlap in the plan view in each pixel P. The signal processing unit 20 is connected to the photoelectric conversion unit 10 via an interconnect provided for each pixel P. The plurality of pixels P are arranged in a two-dimensional array.

Control lines 81 extend in the X direction (first direction) in each row of the pixel array of the circuit substrate 120. The control lines 81 are connected to the signal processing units 20 arranged in the X direction, and form signal lines common to the signal processing units 20. The signal processing units 20 arranged in the same row are controlled by the same control line 81. Each of the control lines 81 may include a plurality of signal lines for supplying a plurality of types of control signals to the signal processing unit 20.

In each column of the pixel array of the circuit substrate 120, the data line 82 extends in the Y direction (second direction) intersecting the X direction. The data lines 82 are connected to the signal processing units 20 of the pixels P arranged in the Y direction, respectively, and form signal lines common to the signal processing units 20. Each of the data lines 82 may include a plurality of signal lines for transferring a digital signal of a plurality of bits output from the signal processing unit 20 in parallel for each bit.

The circuit substrate 120 includes a vertical scanning circuit 30, a readout circuit 40, a horizontal scanning circuit 50, an output circuit 60, and a control circuit 70. These circuits are arranged in a region around the circuit region 121 in the circuit substrate 120.

The vertical scanning circuit 30 receives a control signal from the control circuit 70, generates a control signal for driving the signal processing unit 20, and supplies the control signal to the signal processing unit 20 via the control line 81. The vertical scanning circuit 30 may include logic circuits such as a shift register and an address decoder. The vertical scanning circuit 30 sequentially scans the pixels P of the circuit substrate 120 in units of rows, and sequentially causes the pixels P to output pixel signals to the readout circuit 40 via the data lines 82. Thus, an image of one frame is acquired.

The readout circuit 40 includes a plurality of holding units (not illustrated) provided corresponding to each column of the pixel array. The readout circuit 40 holds the pixel signal of the pixel P of each column output for each row of the pixel array in the holding unit of the corresponding column.

The horizontal scanning circuit 50 receives a control signal from the control circuit 70, sequentially scans the holding unit of each column of the readout circuit 40, and sequentially causes the holding units to output a pixel signal to the output circuit 60. The horizontal scanning circuit 50 may include logic circuits such as a shift register and an address decoder.

The output circuit 60 includes an external interface circuit, and outputs the pixel signal output from the readout circuit 40 to the outside of the photoelectric conversion device 100. The external interface circuit included in the output circuit 60 is not particularly limited. A SerDes (SERializer/DESerializer) transmission circuit can be applied as the external interface circuit. In the SerDes transmission circuit, for example, an LVDS (Low Voltage Differential Signaling) circuit, an SLVS (Scalable Low Voltage Signaling) circuit, or the like can be applied.

The control circuit 70 generates a control signal for controlling operations and timings of the vertical scanning circuit 30, the readout circuit 40, and the horizontal scanning circuit 50, and supplies the control signal to each circuit block. At least a part of the control signal may be supplied from the outside of the photoelectric conversion device 100.

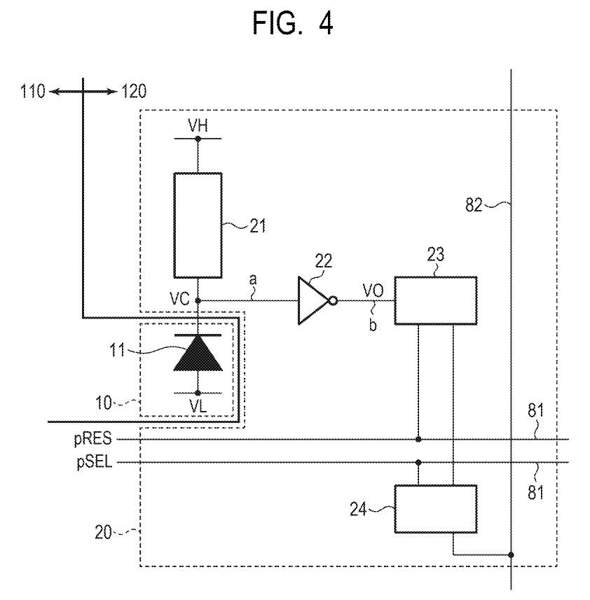

FIG. 4 is a block diagram of the pixel P according to the present embodiment. In the pixel P, the photoelectric conversion unit 10 includes an APD 11, and the signal processing unit 20 includes a quench element (charge circuit) 21, a waveform shaping circuit 22, a count processing unit 23, and a selection circuit 24.

The anode of the APD 11 is connected to a power supply node that supplies a voltage VL (for example, -30 V). The cathode of the APD 11 is connected to one terminal of the quench element 21. A connection node between the APD 11 and the quench element 21 is an output node of the photoelectric conversion unit 10. The other terminal of the quench element 21 is connected to a power supply node that supplies a voltage VH (for example, 1 V) higher than the voltage VL. The voltage VL and the voltage VH are set to be reverse bias voltages that induce avalanche multiplication in the APD 11. Here, a negative high voltage is supplied as the voltage VL, and a positive voltage that is approximately equal to the power supply voltage is supplied as the voltage VH.

When a reverse bias voltage is applied between the anode and the cathode of the APD 11, carriers generated by light incident on the APD 11 cause avalanche multiplication, and an avalanche current is generated. The operation modes in a state where a reverse bias voltage is applied to the APD 11 include a Geiger mode and a linear mode. The Geiger mode is an operation mode in which the reverse bias voltage is set to a voltage higher than the breakdown voltage of the APD 11. The linear mode is an operation mode in which the reverse bias voltage is set to a voltage close to or lower than the breakdown voltage of the APD 11. The APD 11 operated in the Geiger mode is called a SPAD (Single Photon Avalanche Diode). The photoelectric conversion device 100 may operate in either the Geiger mode or the linear mode.

The quench element 21 may be configured by a resistor, a switch, or the like. The quench element 21 functions as a load circuit (quench circuit) during avalanche multiplication, and reduces the reverse bias voltage applied to the APD 11 to suppress the avalanche multiplication. The operation in which the quench element 21 suppresses avalanche multiplication is called a quench operation. In addition, the quench element 21 returns the voltage applied to the APD 11 to a reverse bias voltage capable of avalanche multiplication by supplying to the APD 11 the current that compensates for the voltage drop caused by the quench operation. The operation in which the quench element 21 returns the voltage to the reverse bias voltage is called a charge operation, and the current supplied to the APD 11 in the charge operation is called a charge current.

The waveform shaping circuit 22 includes an inverter circuit (NOT circuit) and has the node a and the node b. An analog signal is input to the node a from the photoelectric conversion unit 10. The waveform shaping circuit 22 shapes the analog signal into a pulse signal and outputs the pulse signal from the node b to the count processing unit 23. Although an example in which the waveform shaping circuit 22 includes one inverter circuit has been described, the waveform shaping circuit 22 is not limited thereto, and may include, for example, a buffer circuit configured by connecting two inverter circuits in series.

The count processing unit 23 includes an input node to which a pulse signal from the waveform shaping circuit 22 is input, a control node to which a control signal from the vertical scanning circuit 30 is input, and an output node. The control signal includes a reset signal pRES for resetting the count value of the count processing unit 23. The count processing unit 23 includes a counter circuit, counts the pulse signal from the waveform shaping circuit 22, holds the count value, and outputs the count value from the output node to the selection circuit 24. When the reset signal pRES is input, the count processing unit 23 resets the count value.

The selection circuit 24 outputs the count value from the count processing unit 23 to the outside of the pixel P. For example, the selection circuit 24 switches the electrical connection between the count processing unit 23 and the data line 82 according to the control signal pSEL from the vertical scanning circuit 30. When the control signal pSEL becomes high level, the selection circuit 24 electrically connects the count processing unit 23 and the data line 82 to output the count value to the data line 82. When the control signal pSEL becomes low level, the selection circuit 24 does not electrically connect the count processing unit 23 and the data line 82, and does not output the count value to the data line 82. The selection circuit 24 may include a buffer circuit for outputting a count value.

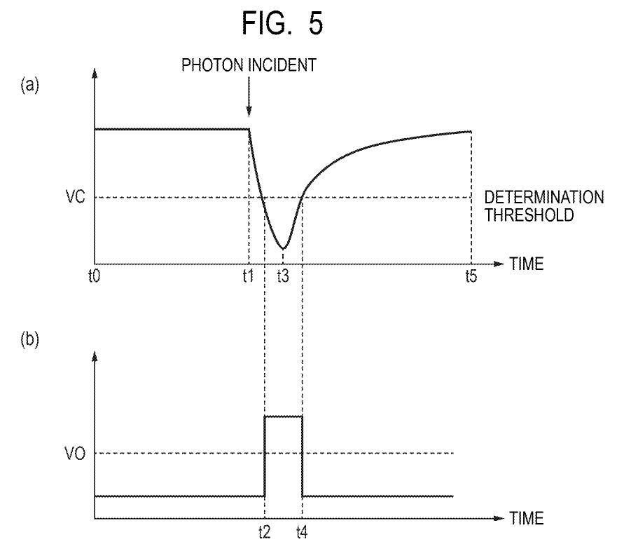

FIG. 5 is a timing chart illustrating the operation of the pixel P according to the present embodiment. FIG. 5 illustrates the voltage VC of the node a of the waveform shaping circuit 22, and the voltage VO of the node b of the waveform shaping circuit 22.

At time t0, the reverse bias voltage (VH-VL) is applied to the APD 11. Although the reverse bias voltage is applied to the APD 11, carriers serving as seeds of avalanche multiplication do not exist in a state where a photon is not incident on the APD 11. Therefore, avalanche multiplication does not occur in the APD 11, and no avalanche current flows through the APD 11.

At time t1, when a photon is incident on the APD 11, an electron-hole pair is generated by photoelectric conversion. Avalanche multiplication occurs using these carriers as seeds, and an avalanche current flows through the APD 11. When the avalanche current flows, the voltage VC of the node a of the waveform shaping circuit 22 starts to drop.

When the amount of drop in the voltage VC increases and the avalanche multiplication stops at time t3, the voltage VC does not drop any more. After the avalanche multiplication is stopped, a charge current that compensates for the voltage drop flows from the power supply node of the voltage VH to the cathode of the APD 11 via the quench element 21, and the voltage VC gradually increases. At time t5, the voltage VC settles to a voltage capable of avalanche multiplication.

The waveform shaping circuit 22 binarizes the signal input from the node a according to a predetermined determination threshold and outputs the binarized signal from the node b. The waveform shaping circuit 22 outputs a low-level signal from the node b when the voltage VC of the node a exceeds the determination threshold, and outputs a high-level signal from the node b when the voltage VC of the node a becomes equal to or less than the determination threshold. For example, since the voltage VC is equal to or lower than the determination threshold in the period from the time t2 to the time t4, the signal level of the node b becomes high level. In addition, since the voltage VC of the node a exceeds the determination threshold in the period from the time t0 to the time t2 and the period from the time t4 to the time t5, the signal level of the node b becomes low level. In this manner, the signal input from the node a is shaped into a high-level signal or a low-level signal by the waveform shaping circuit 22, and is output from the node b.

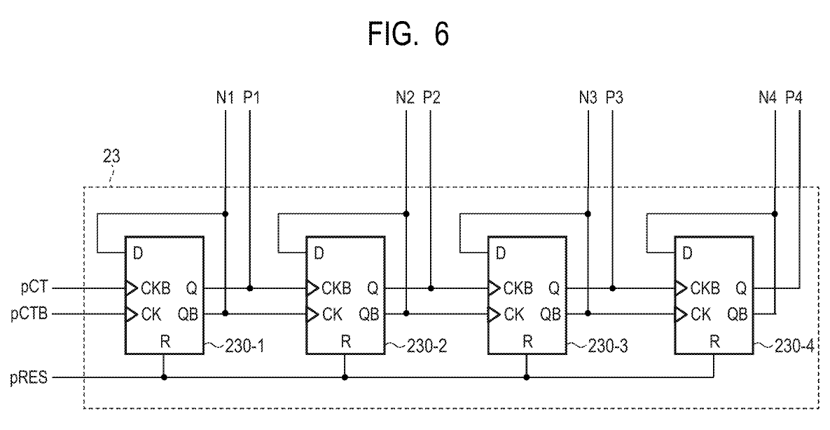

FIG. 6 is a circuit diagram of the count processing unit 23 according to the present embodiment. The count processing unit 23 includes a plurality of (four) flip-flops 230-1 to 230-4, and the bit width of the count processing unit 23 is 4 bits. The count processing unit 23 is an asynchronous type. The pulse signals pCT and pCTB are input to the count processing unit 23 from the waveform shaping circuit 22, and the reset signal pRES is input from the vertical scanning circuit 30. The pulse signal pCTB is an inverted signal of the pulse signal pCT.

The first flip-flop 230-1 corresponds to the least significant bit (LSB) and includes a clock input terminal CK, an inverted clock input terminal CKB, an output terminal Q, an inverted output terminal QB, a data input terminal D, and a reset terminal R. The pulse signal pCTB is input to the clock input terminal CK, and the pulse signal pCT is input to the inverted clock input terminal CKB. The output terminal Q outputs the count signal P1 to the inverted clock input terminal CKB of the second flip-flop 230-2 and the selection circuit 24. The inverted output terminal QB outputs the count signal N1 to the clock input terminal CK of the second flip-flop 230-2, the data input terminal D of the first flip-flop 230-1, and the selection circuit 24. A reset signal pRES is input to the reset terminal R.

The second to fourth flip-flops 230-2 to 230-4 are configured similarly to the first flip-flop 230-1, and output count signals P2 to P4 and N2 to N4. A common reset signal pRES is input to the reset terminals R of the four flip-flops. In the following description, when it is not necessary to distinguish the four flip-flops 230-1 to 230-4, they are simply referred to as the flip-flop 230.

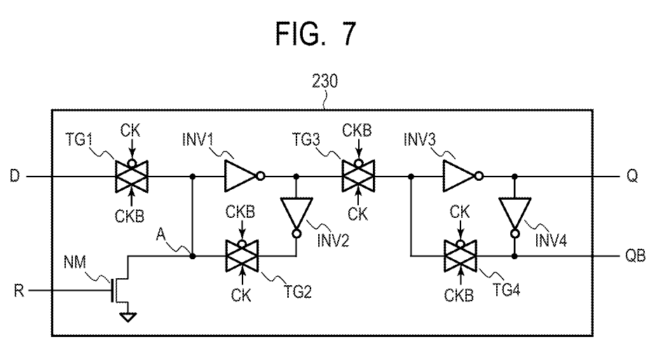

FIG. 7 is a circuit diagram of the flip-flop 230 according to the present embodiment. The flip-flop 230 is a master-slave type in which a master unit and a slave unit are connected in series. The master unit includes inverter circuits INV1 and INV2, transmission gates TG1 and TG2, and a reset transistor NM, and the slave unit includes inverter circuits INV3 and INV4, and transmission gates TG3 and TG4.

Each of the transmission gates TG1 to TG4 includes an NMOS transistor and a PMOS transistor. The drain of the NMOS transistor is connected to the drain of the PMOS transistor, and the source of the NMOS transistor is connected to the source of the PMOS transistor. The gates of the NMOS transistor and the PMOS transistor are connected to the clock input terminal CK or the inverted clock input terminal CKB.

Each of the inverter circuits INV1 to INV4 includes an NMOS transistor and a PMOS transistor. The source of the PMOS transistor is connected to the power supply node, and the source of the NMOS transistor is connected to the ground. The drains of the NMOS transistor and the PMOS transistor are connected to a common output node, and the gates thereof are connected to a common input node.

In the master unit, a signal from the data input terminal D is input to the inverter circuit INV1 via the transmission gate TG1, and an output signal from the inverter circuit INV1 is input to the inverter circuit INV2. The output signal from the inverter circuit INV2 is input to the inverter circuit INV1 via the transmission gate TG2. Thus, the inverter circuits INV1 and INV2 and the transmission gate TG2 form a latch circuit.

In the slave unit, the output signal from the master unit is input to the inverter circuit INV3 via the transmission gate TG3, and the output signal from the inverter circuit INV3 is input to the inverter circuit INV4. The output signal from the inverter circuit INV4 is input to the inverter circuit INV3 via the transmission gate TG4. Thus, the inverter circuits INV3 and INV4 and the transmission gate TG4 form a latch circuit.

In the transmission gates TG1 and TG4, the gates of the NMOS transistors are connected to the inverted clock input terminal CKB, and the gates of the PMOS transistors are connected to the clock input terminal CK. In the transmission gates TG2 and TG3, the gates of the NMOS transistors are connected to the clock input terminal CK, and the gates of the PMOS transistors are connected to the inverted clock input terminal CKB.

When the transmission gates TG2 and TG3 are turned on and the transmission gates TG1 and TG4 are turned off, the count signal held in the master unit is output from the output terminal Q and the inverted output terminal QB. When the transmission gates TG1 and TG4 are turned on and the transmission gates TG2 and TG3 are turned off, the count signal held in the slave unit is output from the output terminal Q and the inverted output terminal QB, and the count signal is input to the master unit from the data input terminal D.

The output terminal Q outputs the count signal from the inverter circuit INV3 to the selection circuit 24, and the inverted output terminal QB outputs to the selection circuit 24 the count signal obtained by inverting the count signal from the inverter circuit INV3 using the inverter circuit INV4.

The reset transistor NM1 is for resetting the count value of the count processing unit 23 and may be an NMOS transistor. In the reset transistor NM1, the drain is connected to the connection node A between the transmission gate TG1 and the transmission gate TG2, the source (main node) is connected to the ground, and the gate (control node) is connected to the vertical scanning circuit 30. When a high-level reset signal pRES is input to the gate from the vertical scanning circuit 30, the reset transistor NM1 is turned on, and the connection node A is electrically connected to the ground. When a low-level reset signal pRES is input to the gate, the reset transistor NM1 is turned off, and the connection node A is not electrically connected to the ground.

When the reset transistor NM1 is turned on in a state where the count signal of the master unit is output, the connection node A is connected to the ground, and a low-level count signal is output from the output terminal Q and a high-level count signal is output from the inverted output terminal QB. Thus, the first flip-flop 230-1 is reset.

When the first flip-flop 230-1 is reset, in the second flip-flop 230-2, a high-level count signal is input to the clock input terminal CK, and a low-level count signal is input to the inverted clock input terminal CKB. As a result, the transmission gates TG2 and TG3 are turned on, the transmission gates TG1 and TG4 are turned off, and the count signal of the master unit is output. When the reset transistor NM1 is turned on in this state, the second flip-flop 230-2 is reset. The third flip-flop 230-3 and the fourth flip-flop 230-4 are reset similarly to the second flip-flop 230-2.

By using the reset transistor NM1 instead of a logic circuit such as a NAND circuit as the reset element, the number of elements of the flip-flop 230 can be reduced. This makes it possible to reduce the size of the count processing unit 23.

Although an example in which one connection node A is reset by one reset transistor NM1 has been described, a configuration in which a plurality of connection nodes are reset by a plurality of reset transistors may be employed.

Next, the layout of the count processing unit 23 on the circuit substrate will be described. First, the layout of the count processing unit according to a comparative example will be described, and then the layout of the count processing unit 23 according to the present embodiment will be described.

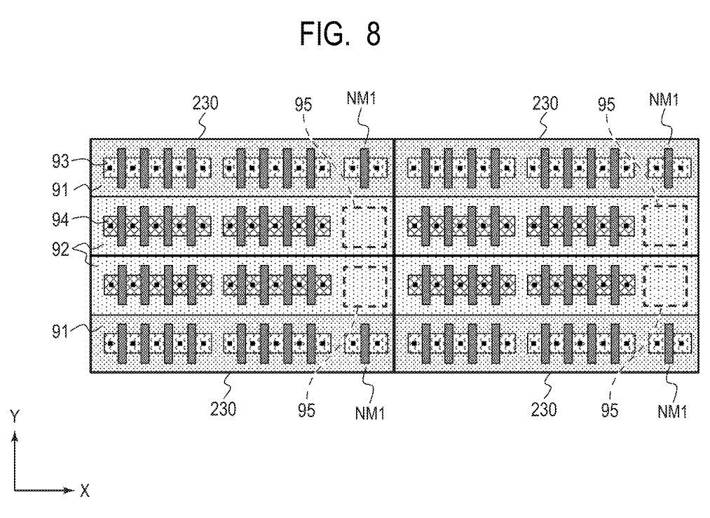

FIG. 8 is the plan view of a count processing unit according to a comparative example. The circuit substrate 120 is a semiconductor substrate such as a silicon substrate or a GaAs substrate, and P-type well regions 91 and N-type well regions 92 are formed in the circuit substrate 120. Each of the P-type well region 91 and the N-type well region 92 has a rectangular shape extending in the long-side direction (X direction). The P-type well region 91, the N-type well region 92, and the P-type well region 91 are arranged in this order in the Y direction intersecting the X direction.

FIG. 8 illustrates transistors constituting four flip-flops 230 corresponding to four bits. The four flip-flops 230 are arranged in a matrix in the X direction and the Y direction, and each includes the P-type well region 91 and the N-type well region 92.

Each flip-flop 230 may be a cell (standard cell) laid out in units of one bit. Generally, transistors need to be formed at least a certain distance away from the boundary of the well region, and it is preferable that the number of boundaries of the well region is small. Therefore, in many cases, standard cells are symmetrically arranged in units of one bit so that well regions of the same conductivity type can be adjacently arranged. As a result, the transistors are efficiently arranged, and expansion of the counter region is suppressed.

The flip-flop 230 includes four pairs of NMOS and PMOS transistors for transmission gates, four pairs of NMOS and PMOS transistors for inverter circuits, and one reset transistor (NMOS transistor). Thus, the flip-flop 230 includes nine NMOS transistors including the reset transistor NM1 and eight PMOS transistors, and the number of NMOS transistors is greater than the number of PMOS transistors.

In each flip-flop 230, N-type active regions 93 are formed in the P-type well region 91. In the P-type well region 91, four NMOS transistors for transmission gates, four NMOS transistors for inverter circuits, and one NMOS transistor (reset transistor NM1) are arranged. A total of nine NMOS transistors are arranged in the P-type well region 91. On the other hand, P-type active regions 94 are formed in the N-type well region 92, and four PMOS transistors for transmission gates and four PMOS transistors for inverter circuits are arranged. A total of eight PMOS transistors are arranged in the N-type well region 92.

Since the number of NMOS transistors is larger than the number of PMOS transistors, when the standard cells of the flip-flop 230 are arranged in units of one bit, a surplus region 95 is generated in the N-type well region 92 of the flip-flop 230. The surplus region 95 is, for example, equal to or larger than the size of one transistor in the plan view. When the surplus region 95 is generated, the area efficiency of the circuit of the pixel P deteriorates.

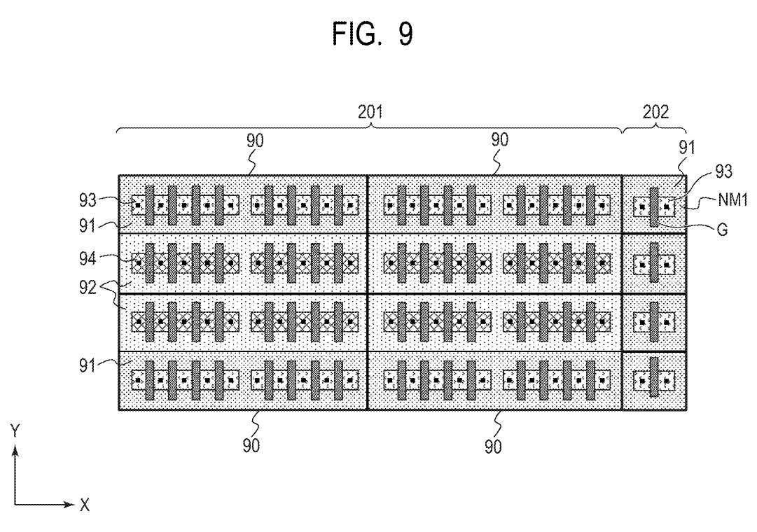

FIG. 9 is the plan view of the count processing unit 23 according to the present embodiment. Hereinafter, differences from the configuration of FIG. 8 will be mainly described. In the circuit substrate 120, the count processing unit 23 is divided into a first region 201 formed of transistors other than the reset transistors NM1 and a second region 202 formed of the reset transistors NM1. Each of the first region 201 and the second region 202 has an elongated rectangular shape in the plan view. The second region 202 is located in the X direction with respect to the first region 201, and the long side of the second region 202 is in contact with the short side of the first region 201. The length of the long side of the second region 202 corresponds to the length of the short side of the first region 201, and the first region 201 and the second region 202 form a rectangular shape in the plan view as a whole.

The first region 201 includes P-type well regions 91 and N-type well regions 92. The P-type well region 91 and the N-type well region 92 each extends in the X direction, and the P-type well region 91, the N-type well region 92, and the P-type well region 91 are arranged in order in the Y direction.

The first region 201 is divided into four regions 90 arranged in a matrix in the X direction and the Y direction. Each of the plurality of regions 90 includes the P-type well region 91 and the N-type well region 92.

In each region 90, transistors other than the reset transistor NM1 in the one-bit flip-flop 230, that is, transistors for transmission gates and inverter circuits are arranged. Specifically, in the region 90, N-type active regions 93 are formed in the P-type well region 91, and four NMOS transistors for transmission gates and four NMOS transistors for inverter circuits are formed in the N-type active regions 93. Therefore, a total of eight NMOS transistors are arranged in the P-type well region 91 of the region 90. On the other hand, P-type active regions 94 are formed in the N-type well region 92, and four PMOS transistors for transmission gates and four PMOS transistors for inverter circuits are formed in the P-type active regions 94. Therefore, a total of eight PMOS transistors are arranged in the N-type well region 92 of the region 90.

The region 90 includes eight NMOS transistors and eight PMOS transistors. Therefore, the first region 201 includes the same number (thirty-two) of NMOS transistors and PMOS transistors. The thirty-two NMOS transistors and the thirty-two PMOS transistors are arranged in a matrix in the X direction and the Y direction in the first region 201.

The second region 202 includes the P-type well region 91 and does not include the N-type well region 92. The P-type well region 91 extends in the Y direction, and N-type active regions 93 are formed in the P-type well region 91. In the N-type active regions 93, four NMOS transistors (reset transistors NM1) are arranged side by side in the Y direction. The number (four) of the reset transistors NM1 in the Y direction and the number (four) of the transistors in the first region 201 in the Y direction are the same.

As described above, the count processing unit 23 is divided into the first region 201 including the same number of NMOS transistors and PMOS transistors and the second region 202 including either NMOS transistors or PMOS transistors. With such a configuration, it is possible to eliminate the surplus region 95 in the count processing unit 23, reduce the area of the count processing unit 23, and improve the area efficiency of the circuit. In particular, since the count processing unit 23 is often configured to have multiple bits and the circuit scale tends to be larger than that of a simple logic circuit, the effect of the area efficiency due to the miniaturization of the count processing unit 23 is large. As a result, it is possible to suppress an increase in the circuit area of the count processing unit, realize a multi-bit configuration of the count processing unit 23, and add a circuit for improving performance and function.

The lengths of the first region 201 and the second region 202 in the Y direction are equal to each other, and the first region 201 and the second region 202 disposed adjacent to each other have a rectangular shape as a whole. Therefore, it is possible to increase the degree of freedom of the layout of the count processing unit 23 in the signal processing unit 20.

Among the four regions 90 included in the first region 201, two regions 90 are adjacent to the second region 202, but the other two regions 90 are not adjacent to the second region 202. Therefore, the distance between the connection node A of the other two regions 90 and the reset transistors NM1 in the second region 202 may be long. In this case, it is preferable to connect the connection node A and the reset transistor NM1 by a metal interconnect to suppress an increase in interconnect impedance. However, when a circuit other than the count processing unit 23 is disposed in the first region 201 and the second region 202, the interconnect layout may be restricted. Therefore, from the viewpoint of the degree of freedom of the interconnect layout, it is preferable not to arrange circuits other than the count processing unit 23 in the first region 201 and the second region 202.

### Second Embodiment

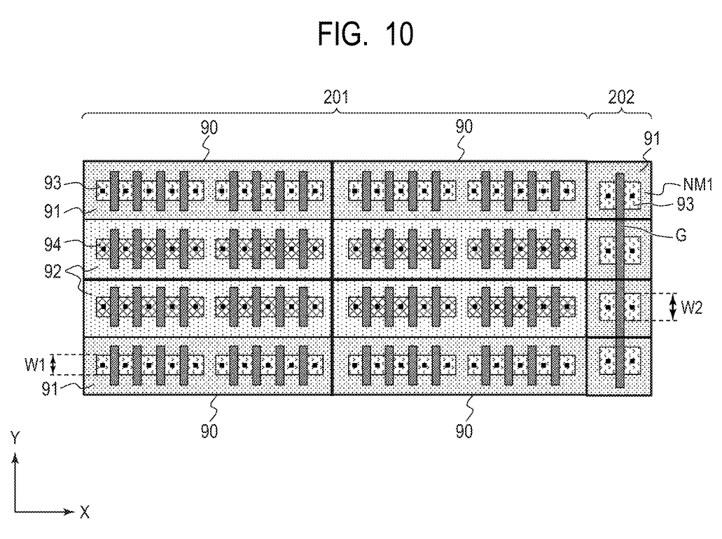

FIG. 10 is the plan view of a count processing unit 23 according to the present embodiment. The present embodiment is different from the first embodiment in that a plurality of reset transistors NM1 have a common gate. Hereinafter, differences from the first embodiment will be mainly described.

The gate (gate electrode) G is formed of, for example, polysilicon, and is a common electrode formed over the four reset transistors NM1. Since the space between the gates of the adjacent reset transistors NM1 can be reduced, the width (length in the short-side direction) W2 of the active region of the reset transistor NM1 can be increased. For example, the width W2 of the active region of the reset transistor NM1 is larger than the width W1 of the active region of the transistor in the first region 201. As a result, the drive capability of the reset transistor NM1 becomes higher than the drive capability of the transistors (transistors for transmission gates and inverter circuits) in the first region 201.

When the count processing unit 23 is reset, a reset signal pRES is input to the gate G of each reset transistor NM1. When the reset signal pRES is input, the reset transistor NM1 resets the voltage of the connection node A, but it is necessary to reset the voltage within a predetermined control time, and it is preferable that the drive capability of the reset transistor NM1 is high. When the drive capability of the reset transistor NM1 is high, the photoelectric conversion device 100 can reset the count processing unit 23 within the control time, and the reliability can be improved.

### Third Embodiment

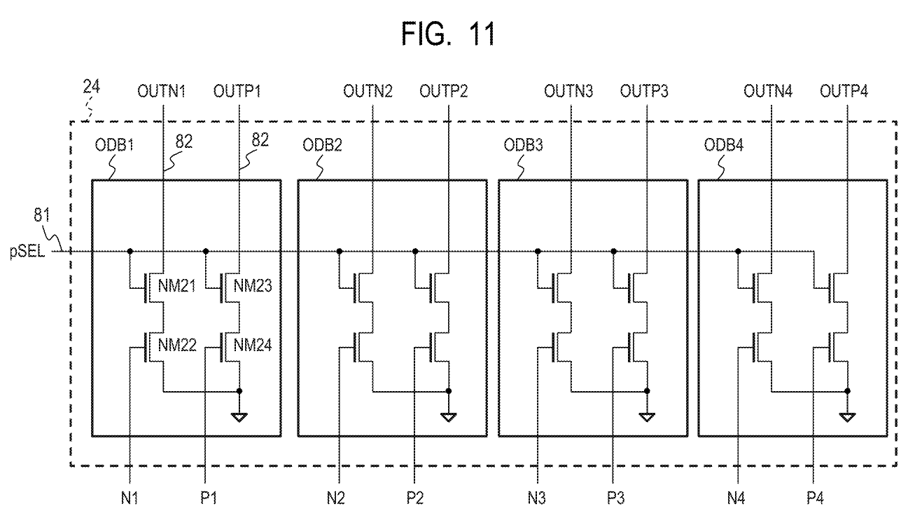

FIG. 11 is a circuit diagram of a selection circuit 24 according to the present embodiment. The present embodiment is different from the first embodiment in that the second region 202 includes open-drain buffers ODB1 to ODB4 of the selection circuit 24. Hereinafter, differences from the first embodiment will be mainly described.

The selection circuit 24 includes a plurality of (four) open-drain buffers ODB1 to ODB4 corresponding to the number of bits (four bits) of the count processing unit 23. Count signals N1 and P1 of opposite polarities are input to the open-drain buffer ODB1 from the LSB flip-flop 230, and output signals OUTN1 and OUTP1 of opposite polarities are output. The open-drain buffer ODB1 includes NMOS transistors NM21 to NM24.

The drain of the NMOS transistor NM21 is connected to the data line 82, the source of the NMOS transistor NM21 is connected to the drain of the NMOS transistor NM22, and the source of the NMOS transistor NM22 is connected to the ground. The control signal pSEL is supplied from the vertical scanning circuit 30 to the gate of the NMOS transistor NM21, and the count signal N1 is input to the gate of the NMOS transistor NM22.

The drain of the NMOS transistor NM23 is connected to the data line 82, the source of the NMOS transistor NM23 is connected to the drain of the NMOS transistor NM24, and the source of the NMOS transistor NM24 is connected to the ground. The control signal pSEL is supplied from the vertical scanning circuit 30 to the gate of the NMOS transistor NM23, and the count signal P1 is input to the gate of the NMOS transistor NM24.

The open-drain buffers ODB2 to ODB4 are configured similarly to the open-drain buffer ODB1. The count signals N2 and P2 from the flip-flop 230 of the second bit are input to the open-drain buffer ODB2, and the count signals N3 and P3 from the flip-flop 230 of the third bit are input to the open-drain buffer ODB3. Count signals N4 and P4 from the flip-flop 230 of the MSB (Most Significant Bit) are input to the open-drain buffer ODB4.

When the control signal pSEL becomes high level, the NMOS transistors NM21 and NM23 are turned on. At this time, the selection circuit 24 outputs output signals OUTN1 to OUTN4 and OUTP1 to OUTP4 having mutually opposite polarities to the readout circuit 40 in accordance with the count signals P1 to P4 and N1 to N4 having mutually opposite polarities. For example, in the open-drain buffer ODB1, when the count signal N1 is at high level, the NMOS transistor NM22 is turned on, and the selection circuit 24 outputs a low-level output signal OUTN1 to the readout circuit 40. When the count signal N1 is at low level, the NMOS transistor NM22 is turned off, and the selection circuit 24 outputs a high-level output signal OUTN1 to the readout circuit 40. On the other hand, when the control signal pSEL becomes low level, the NMOS transistors NM21 and NM23 are turned off, and the count signals P1 to P4 and N1 to N4 are not output to the readout circuit 40.

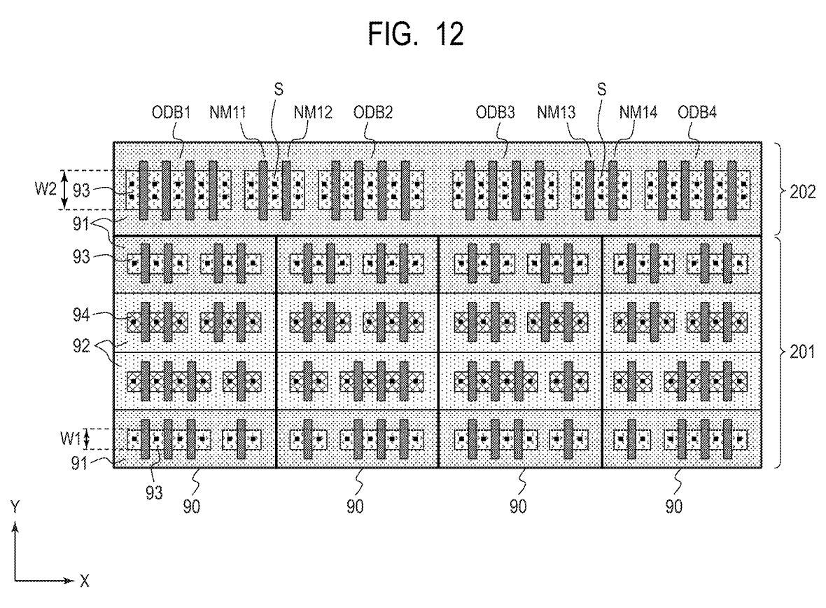

FIG. 12 is the plan view of the count processing unit 23 and the selection circuit 24 according to the present embodiment. In the circuit substrate 120, the count processing unit 23 and the selection circuit 24 are divided into a first region 201 and a second region 202. The first region 201 includes transistors other than the reset transistors of the count processing unit 23. The second region 202 includes the reset transistors NM11 to NM14 and the transistors of the open-drain buffers ODB1 to ODB4. Each of the first region 201 and the second region 202 has an elongated rectangular shape in the plan view. The second region 202 is located in the Y direction with respect to the first region 201, and the long side of the second region 202 is in contact with the long side of the first region 201. The length of the long side of the second region 202 corresponds to the length of the long side of the first region 201, and the first region 201 and the second region 202 form a rectangular shape in the plan view as a whole.

The well region of the first region 201 has the same configuration as the well region of the first region 201 in FIG. 9. The first region 201 is divided into four regions 90 arranged side by side in the X direction. Each of the regions 90 includes P-type well regions 91 and N-type well regions 92.

In each region 90, transistors other than the reset transistor in the one-bit flip-flop 230, that is, transistors for transmission gates and inverter circuits are arranged. Specifically, in the region 90, N-type active regions 93 are formed in the P-type well region 91, and four NMOS transistors for transmission gates and four NMOS transistors for inverter circuits are formed in the N-type active regions 93. Therefore, a total of eight NMOS transistors are arranged in the P-type well regions 91 of the region 90. On the other hand, P-type active regions 94 are formed in the N-type well regions 92, and four PMOS transistors for transmission gates and four PMOS transistors for inverter circuits are formed in the P-type active regions 94. Therefore, a total of eight PMOS transistors are arranged in the N-type well regions 92 of the region 90.

The region 90 includes eight NMOS transistors and eight PMOS transistors. Therefore, the first region 201 includes the same number (thirty-two) of NMOS transistors and PMOS transistors. The thirty-two NMOS transistors and the thirty-two PMOS transistors are arranged in a matrix in the X direction and the Y direction in the first region 201.

The second region 202 includes the P-type well region 91 and does not include the N-type well region 92. The P-type well region 91 extends in the X direction, and N-type active regions 93 are formed in the P-type well region 91. In the N-type active regions 93, twenty NMOS transistors are arranged side by side in the X direction. The twenty NMOS transistors include four reset transistors NM11 to NM14 and sixteen NMOS transistors of open-drain buffers ODB1 to ODB4, and the twenty NMOS transistors are adjacent to each other.

As described above, the count processing unit 23 and the selection circuit 24 are divided into the first region 201 including the same number of NMOS transistors and PMOS transistors and the second region 202 including either NMOS transistors or PMOS transistors. With such a configuration, it is possible to eliminate the surplus region 95 in the count processing unit 23 and the selection circuit 24, reduce the area of the count processing unit 23 and the selection circuit 24, and improve the area efficiency of the circuit.

In the second region 202, the first reset transistor NM11 and the second reset transistor NM12 share a source region S. The third reset transistor NM13 and the fourth reset transistor NM14 share a source region S. By sharing the source region S, the size of the count processing unit 23 can be reduced.

The width (length in the short-side direction) W2 of the active regions of the open-drain buffers ODB1 to ODB4 is larger than the width W1 of the active region of the transistor in the first region 201. Therefore, the drive capability of the transistors of the open-drain buffers ODB1 to ODB4 is higher than the drive capability of the transistors of the first region 201. Accordingly, the open-drain buffers ODB1 to ODB4 can stably output the count signal from the count processing unit 23 to the readout circuit 40 in a short time.

The width W2 of the active regions of the open-drain buffers ODB1 to ODB4 is the same as the width W2 of the active regions of the reset transistors NM11 to NM14. With this configuration, it is possible to sufficiently obtain the drive capability of the transistors of the open-drain buffers ODB1 to ODB4 and the drive capability of the reset transistors NM11 to NM14.

Since each of the short sides of the four regions 90 is in contact with the long side of the second region 202, it is possible to suppress an increase in the distance between the connection node of each flip-flop 230 and the reset transistor, thereby simplifying the interconnect layout.

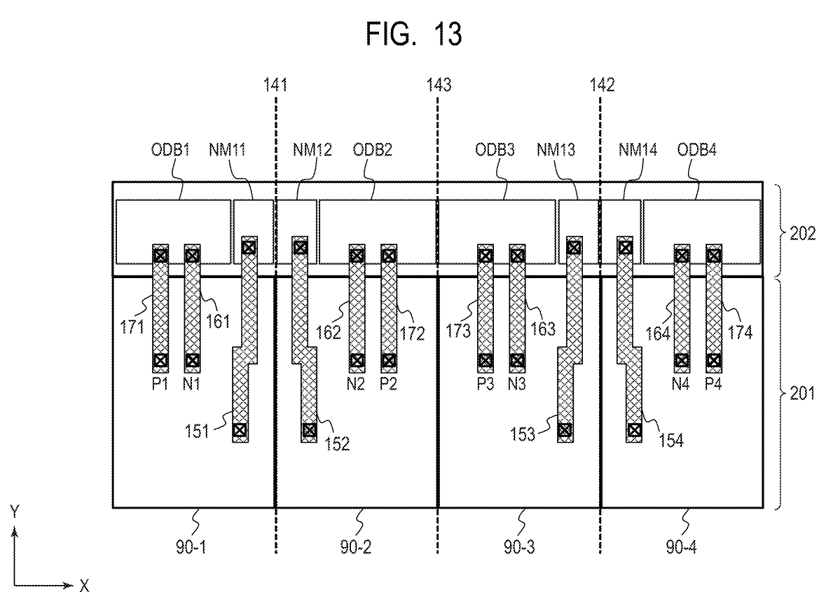

FIG. 13 is the plan view of an interconnect layer of the count processing unit 23 and the selection circuit 24 according to the present embodiment. The layout of the semiconductor layers in the first region 201 and the second region 202 in FIG. 13 is the same as the layout of the semiconductor layers in FIG. 12. FIG. 13 illustrates a part of the interconnect layer located above the semiconductor layer.

The interconnect layer includes a plurality of interconnects 151 to 154, 161 to 164 and 171 to 174. The interconnects (first interconnects) 151 to 154 extend in the Y direction and are formed so as to straddle the first region 201 and the second region 202. The interconnect 151 connects the connection node of the flip-flop 230 in the first region 90-1 and the reset transistor NM11 in the second region 202. The interconnect 152 connects the connection node of the flip-flop 230 in the second region 90-2 and the reset transistor NM12 in the second region 202. The interconnect 153 is formed in the same manner as the interconnect 151, and the interconnect 154 is formed in the same manner as the interconnect 152.

The interconnects (second interconnects) 161 to 164 extend in the Y direction and are formed so as to straddle the first region 201 and the second region 202. The interconnect 161 connects the inverted output terminal of the flip-flop 230 in the first region 90-1 and the open-drain buffer ODB1 in the second region 202, and transmits the count signal N1. The interconnect 162 connects the inverted output terminal of the flip-flop 230 in the second region 90-2 and the open-drain buffer ODB2 in the second region 202, and transmits the count signal N2. The interconnect 163 is formed in the same manner as the interconnect 161, and transmits the count signal N3. The interconnect 164 is formed in the same manner as the interconnect 162, and transmits the count signal N4.

The interconnects (second interconnects) 171 to 174 extend in the Y direction and are formed so as to straddle the first region 201 and the second region 202. The interconnect 171 connects the output terminal of the flip-flop 230 in the first region 90-1 and the open-drain buffer ODB1 in the second region 202, and transmits the count signal P1. The interconnect 172 connects the output terminal of the flip-flop 230 in the second region 90-2 and the open-drain buffer ODB2 in the second region 202, and transmits the count signal P2. The interconnect 173 is formed in the same manner as the interconnect 171, and transmits the count signal P3. The interconnect 174 is formed in the same manner as the interconnect 172, and transmits the count signal P4.

The interconnect 151 and the interconnect 152 are arranged line-symmetrically with respect to the boundary line 141 between the first region 90-1 and the second region 90-2. Similarly, the interconnect 161 and the interconnect 162, and the interconnect 171 and the interconnect 172 are also arranged line-symmetrically with respect to the boundary line 141. The interconnect 153 and the interconnect 154 are arranged line-symmetrically with respect to the boundary line 142 between the third region 90-3 and the fourth region 90-4. Similarly, the interconnect 163 and the interconnect 164, and the interconnect 173 and the interconnect 174 are also arranged line-symmetrically with respect to the boundary line 142. As a result, the interconnects in the regions 90-1 and 90-2 and the interconnects in the regions 90-3 and 90-4 are arranged line-symmetrically with respect to the boundary line 143 between the second region 90-2 and the third region 90-3. As described above, the count processing unit 23 and the selection circuit 24 are common layout cells for each bit, and are symmetrically arranged for each bit.

As described above, the interconnects 151 to 154, 161 to 164 and 171 to 174 are formed without intersecting with each other in the same interconnect layer. Such a single-layer and simple interconnect layout not only reduces restrictions on the interconnect layout but also improves the area efficiency of the interconnect of the pixel P. When the count processing unit 23 and the selection circuit 24 are disposed in the limited region, it is preferable to increase the area efficiency as much as possible in the interconnect layer in addition to the semiconductor layer.

Although an example in which the open-drain buffers ODB1 to ODB4 are disposed in the second region 202 has been described in the present embodiment, another circuit may be disposed in the second region 202. There is no particular limitation on the circuit included in the second region 202 as long as it includes transistors having the same conductivity type as the reset transistor in the second region 202.

### Fourth Embodiment

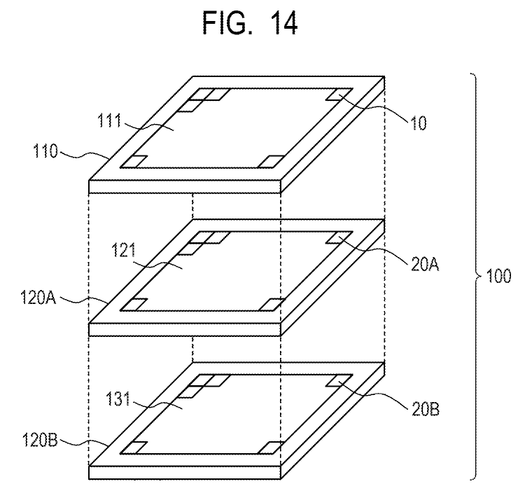

FIG. 14 is an exploded perspective view of a photoelectric conversion device 100 according to the present embodiment. The photoelectric conversion device 100 includes a sensor substrate (first substrate) 110, a circuit substrate (third substrate) 120A, and a circuit substrate (second substrate) 120B that are stacked and electrically connected to each other. The sensor substrate 110 has a pixel region 111, the circuit substrate 120A has a circuit region 121, and the circuit substrate 120B has a circuit region 131. The photoelectric conversion device 100 includes a plurality of pixels, and each pixel includes a photoelectric conversion unit 10, a signal processing unit 20A, and a signal processing unit 20B. The photoelectric conversion unit 10 is disposed in the pixel region 111, the signal processing unit 20A is disposed in the circuit region 121, and the signal processing unit 20B is disposed in the circuit region 131.

The sensor substrate 110 has a first semiconductor layer including the photoelectric conversion unit 10 and a first interconnect structure including interconnects. The circuit substrate 120A has a second semiconductor layer including the signal processing unit 20A, and a second interconnect structure including interconnects. The circuit substrate 120B has a third semiconductor layer including the signal processing unit 20B, and a third interconnect structure including interconnects. In the photoelectric conversion device 100, the third semiconductor layer, the third interconnect structure, the second semiconductor layer, the second interconnect structure, the first interconnect structure, and the first semiconductor layer are stacked in this order. The photoelectric conversion device 100 is a back-illuminated type in which light is incident from the second surface of the first semiconductor layer and the circuit substrate 120A is provided on the first surface of the first semiconductor layer.

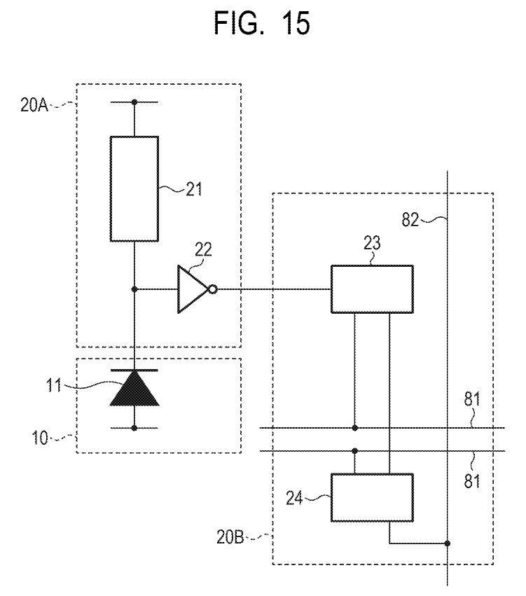

FIG. 15 is a block diagram of a pixel according to the present embodiment. The photoelectric conversion unit 10 includes an APD 11. The signal processing unit 20A includes a quench element 21 and a waveform shaping circuit 22. The signal processing unit 20B includes a count processing unit 23 and a selection circuit 24, and is formed on the circuit substrate 120B in the layout described in the first to third embodiments.

### Fifth Embodiment

Although the photoelectric conversion element is described as an APD in the above-described embodiment, the photoelectric conversion element is not limited thereto, and may be, for example, a PIN photodiode. In the present embodiment, differences from the first embodiment will be mainly described.

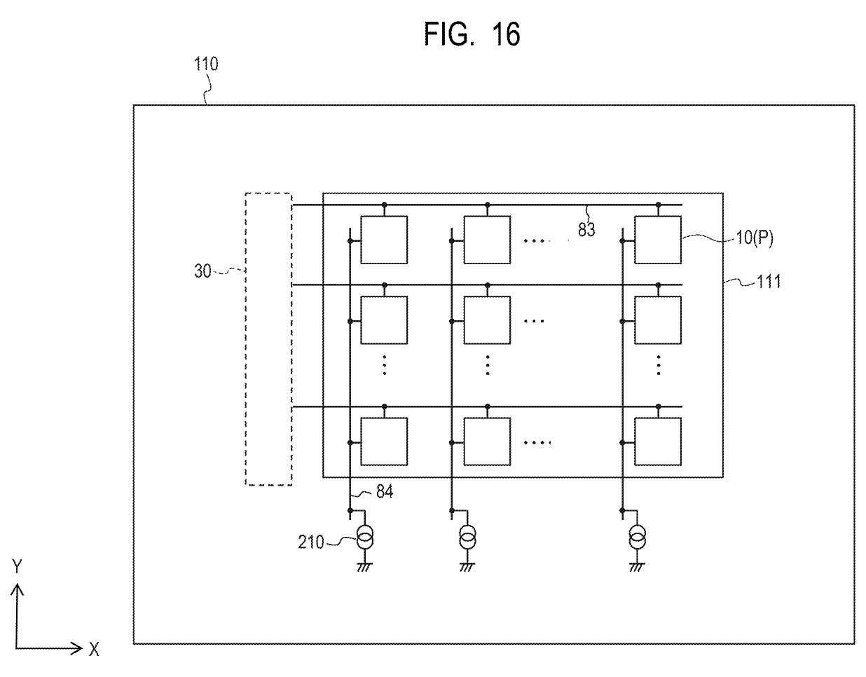

FIG. 16 is a block diagram of a sensor substrate 110 according to the present embodiment. In the pixel region 111 of the sensor substrate 110, the photoelectric conversion units 10 of the pixels P are arranged in a two-dimensional array in the plan view. The photoelectric conversion units 10 in the pixel region 111 may be arranged in a one-dimensional array.

Control lines 83 extend in the X direction (first direction) in each row of the pixel array of the sensor substrate 110. The control lines 83 are connected to the photoelectric conversion units 10 arranged in the X direction, respectively, and form signal lines common to the photoelectric conversion units 10. The photoelectric conversion units 10 arranged in the same row are controlled by the same control line 83. Each of the control lines 83 may include a plurality of signal lines for supplying a plurality of types of control signals to the photoelectric conversion unit 10.

The sensor substrate 110 includes a current source 210 disposed in a region around the pixel region 111. The current source 210 constitutes a source follower described later.

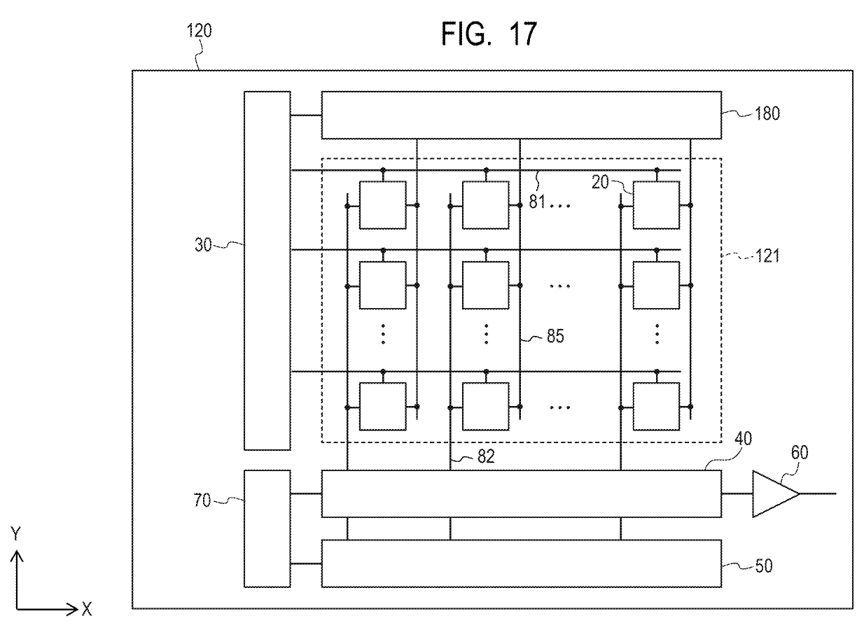

FIG. 17 is a block diagram of a circuit substrate 120 according to the present embodiment. In the circuit region 121 of the circuit substrate 120, the signal processing units 20 are arranged in a two-dimensional array in the plan view. The pixel region 111 and the circuit region 121 overlap in the plan view, and at least a part of the photoelectric conversion unit 10 and the signal processing unit 20 overlap in the plan view in each pixel P. The signal processing unit 20 is connected to the photoelectric conversion unit 10 via an interconnect provided for each pixel P. The plurality of pixels P are arranged in a two-dimensional array.

In each column of the pixel array of the circuit substrate 120, data lines 82 and signal lines 85 extend in the Y direction (second direction) intersecting the X direction. The data lines 82 and the signal lines 85 are connected to the signal processing units 20 of the pixels P arranged in the Y direction, respectively, and form signal lines common to the signal processing units 20. Each of the data lines 82 may include a plurality of signal lines for transferring a digital signal of a plurality of bits output from the signal processing unit 20 in parallel for each bit. Each of the signal lines 85 may include a plurality of signal lines for supplying a plurality of types of control signals to the signal processing unit 20.

The circuit substrate 120 includes a vertical scanning circuit 30, a readout circuit 40, a horizontal scanning circuit 50, an output circuit 60, a control circuit 70, and a ramp generation circuit 180. These circuits are arranged in a region around the circuit region 121 in the circuit substrate 120.

The vertical scanning circuit 30 generates a control signal for driving the photoelectric conversion unit 10 of the sensor substrate 110, and supplies the control signal to the photoelectric conversion unit 10 via the control line 83 of the sensor substrate 110, as illustrated in FIG. 16. In addition, as illustrated in FIG. 17, the vertical scanning circuit 30 sequentially scans the pixels P of the circuit substrate 120 in units of rows via the control lines 81, and sequentially causes the pixels P to output their pixel signals to the readout circuit 40 via the data lines 82. Thus, an image of one frame is acquired. The vertical scanning circuit 30 may include logic circuits such as a shift register and an address decoder.

Each of the readout circuit 40, the horizontal scanning circuit 50, the output circuit 60, and the control circuit 70 has the same configuration as that of the circuit described with reference to FIG. 3.

The ramp generation circuit 180 receives a control signal from the control circuit 70, generates a ramp signal and a count signal, and supplies them to the signal processing unit 20 via the signal line 85. Here, the ramp signal is a signal whose signal voltage changes with time at a predetermined voltage change rate. The count signal is a signal of a plurality of bits that is synchronized with the ramp signal and counted up according to the elapsed time. The ramp generation circuit 180 may include logic circuits such as a ramp generator and a counter.

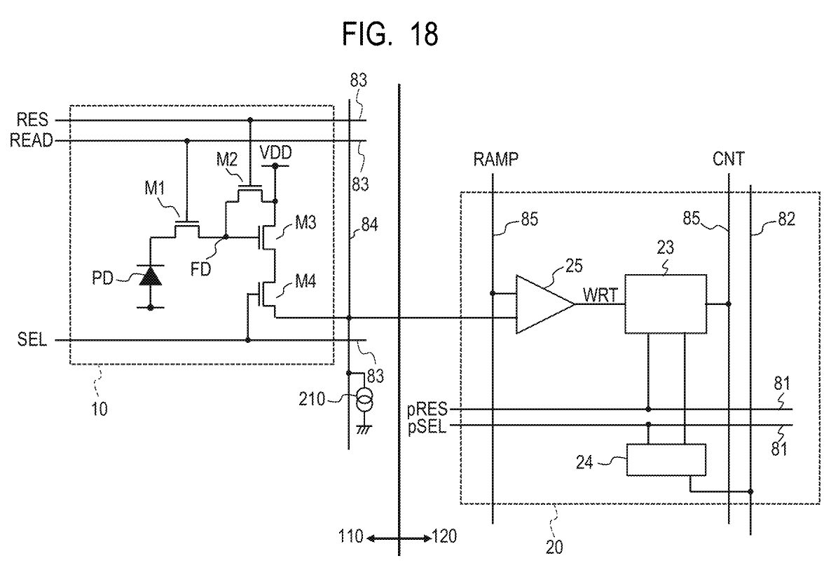

FIG. 18 is a block diagram of the pixel P according to the present embodiment. In the pixel P, the photoelectric conversion unit 10 includes a photodiode PD as a photoelectric conversion element, a transfer transistor M1, a reset transistor M2, an amplifier transistor M3, and a selection transistor M4. The signal processing unit 20 includes a comparator 25, a count processing unit 23, and a selection circuit 24.

The photodiode PD is, for example, a PIN photodiode, and has the anode connected to the ground voltage line and the cathode connected to the source of the transfer transistor M1. The drain of the transfer transistor M1 is connected to the source of the reset transistor M2 and the gate of the amplifier transistor M3. The node FD to which the drain of the transfer transistor M1, the source of the reset transistor M2, and the gate of the amplifier transistor M3 are connected is a so-called floating diffusion portion. The floating diffusion portion includes a capacitance component (floating diffusion capacitance) and has a function as a charge holding portion. The floating diffusion capacitance may include a gate capacitance of the transistor, a pn junction capacitance, an interconnect capacitance, and the like. The drain of the reset transistor M2 and the drain of the amplifier transistor M3 are connected to a node to which a power supply voltage (for example, the voltage VDD) is supplied. The source of the amplifier transistor M3 is connected to the drain of the selection transistor M4. The source of the selection transistor M4 is connected to the signal line 84.

The control lines 83 arranged in each row of the pixel region 111 include three signal lines connected to the gate of the transfer transistor M1, the gate of the reset transistor M2, and the gate of the selection transistor M4. A read pulse READ is supplied from the vertical scanning circuit 30 to the gate of the transfer transistor M1. A reset pulse RES is supplied from the vertical scanning circuit 30 to the gate of the reset transistor M2. A selection pulse SEL is supplied from the vertical scanning circuit 30 to the gate of the selection transistor M4. In the case where each transistor is formed of an N-type transistor, when a high-level control signal is supplied from the vertical scanning circuit 30, the corresponding transistor is turned on. When a low-level control signal is supplied from the vertical scanning circuit 30, the corresponding transistor is turned off.

The present embodiment will be described on the assumption that electrons among electron-hole pairs generated in the photodiode PD by light incidence are used as signal charges. When electrons are used as the signal charge, each transistor constituting the pixel P may be formed of an N-type transistor. However, the signal charge is not limited to electrons, and holes may be used as the signal charge. When holes are used as the signal charge, the conductivity type of each transistor is opposite to that described in the present embodiment. The names of the source and the drain of the MOS transistor may vary depending on the conductivity type of the transistor and the function of the transistor. Some or all of the names of the source and the drain used in the present embodiment may be reversed.

In the shutter operation, the charge of the photodiode PD is reset by turning on the transfer transistor M1 and the reset transistor M2. When reading is performed, after the reset transistor M2 is turned on to reset the node FD, the transfer transistor M1 is turned on to transfer the charge accumulated in the photodiode PD to the node FD. The charge is converted into a voltage by the capacitance associated with the node FD. The selection transistors M4 are sequentially turned on row by row by the vertical scanning circuit 30. When the selection transistor M4 is turned on, the voltage is output to the signal line 84 by the source follower constituted by the amplifier transistor M3 and the current source 210.

The comparator 25 compares the voltage signal output to the signal line 84 with the ramp signal RAMP from the ramp generation circuit 180. When the voltage signal of the signal line 84 becomes equal to the ramp signal RAMP, the comparator 25 outputs the pulse signal WRT to the count processing unit 23 according to the comparison result.

The count processing unit 23 includes a latch circuit, and latches the count signal CNT from the ramp generation circuit 180 when receiving the pulse signal WRT from the comparator 25. In this way, the count processing unit 23 counts the time until the ramp signal RAMP becomes equal to the voltage signal of the signal line 84.

Since the voltage signal of the signal line 84 differs depending on the amount of charge generated by exposure of the photoelectric conversion unit 10, the count value of the count processing unit 23 differs for each photoelectric conversion unit 10 depending on the intensity of incident light. The count value is a value obtained by converting an analog signal from the photoelectric conversion unit 10 into a digital signal. The digital signal as the count value is output to the data line 82 via the selection circuit 24.

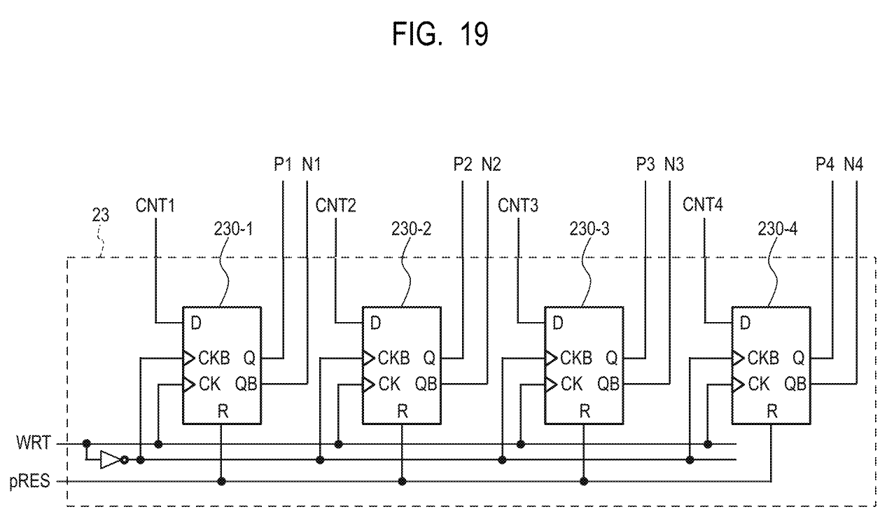

FIG. 19 is a circuit diagram of the count processing unit 23 according to the present embodiment. The count processing unit 23 includes a plurality of (four) flip-flops 230-1 to 230-4, and the bit width of the count processing unit 23 is 4 bits. The count processing unit 23 receives the pulse signal WRT from the comparator 25, the reset signal pRES from the vertical scanning circuit 30, and the count signals CNT (CNT1 to CNT4) from the ramp generation circuit 180.

The first flip-flop 230-1 corresponds to the LSB and includes a clock input terminal CK, an inverted clock input terminal CKB, an output terminal Q, an inverted output terminal QB, a data input terminal D, and a reset terminal R. A pulse signal WRT is input to the clock input terminal CK, and an inverted signal of the pulse signal WRT is input to the inverted clock input terminal CKB. The output terminal Q outputs a count signal P1 to the selection circuit 24, and the inverted output terminal QB outputs a count signal N1 to the selection circuit 24. The count signal CNT1 corresponding to LSB among the 4-bit count signals is input to the data input terminal D of the first flip-flop 230-1, and the reset signal pRES is input to the reset terminal R.

The second flip-flop 230-2 to the fourth flip-flop 230-4 are configured similarly to the first flip-flop 230-1, and output count signals P2 to P4 and N2 to N4. A common reset signal pRES is input to the reset terminals R of the four flip-flops 230. A count signal CNT2 corresponding to the second bit among the 4-bit count signals is input to the data input terminal D of the flip-flop 230-2. Similarly, count signals CNT3 and CNT4 corresponding to the third bit and the fourth bit (MSB) of the count signal are input to the data input terminals D of the flip-flops 230-3 and 230-4.

For example, as illustrated in FIG. 7, the flip-flop 230 may be a circuit that latches the count signal CNT in response to the pulse signal WRT.

As illustrated in FIG. 9, the count processing unit 23 according to the present embodiment is divided into a first region 201 and a second region 202. The first region 201 includes the same number of NMOS transistors and PMOS transistors. The second region 202 includes either NMOS transistors or PMOS transistors.

As described above, according to the present embodiment, even when a photodiode other than an APD is used as a photoelectric conversion element, it is possible to reduce the area of the count processing unit 23 and improve the area efficiency of the circuit.

Although the current source 210 and the signal line 84 are disposed on the sensor substrate 110 in the present embodiment, the present disclosure is not limited thereto, and they may be disposed on the circuit substrate 120.

### Sixth Embodiment

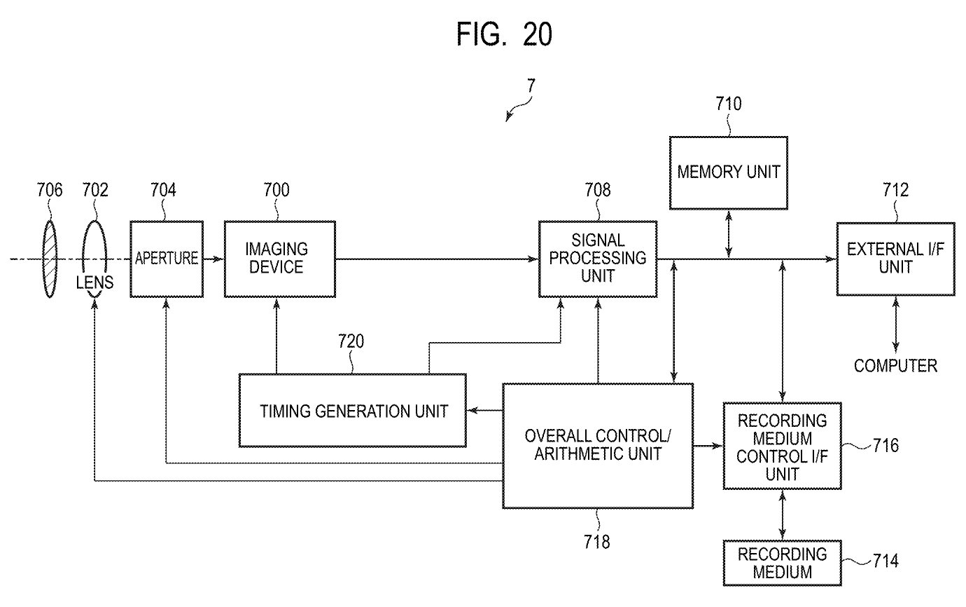

The photoelectric conversion device 100 in the above-described embodiment can be applied to various equipment. Examples of the equipment include a digital still camera, a digital camcorder, a camera head, a copier, a fax machine, a mobile phone, an in-vehicle camera, an observation satellite, and a monitoring camera. FIG. 20 is a block diagram of a digital still camera as an example of the equipment.

The equipment 7 illustrated in FIG. 20 includes a barrier 706, a lens 702, an aperture 704, and an imaging device 700 (an example of a photoelectric conversion device). The equipment 7 further includes a signal processing unit (processing device) 708, a timing generation unit 720, an overall control/arithmetic unit 718 (control device), a memory unit 710 (storage device), a recording medium control I/F unit 716, a recording medium 714, and an external I/F unit 712. At least one of the barrier 706, the lens 702, and the aperture 704 is an optical device corresponding to the equipment 7. The barrier 706 protects the lens 702, and the lens 702 forms an optical image of an object on the imaging device 700. The aperture 704 adjusts the amount of light passing through the lens 702. The imaging device 700 is configured as in the above-described embodiment, and converts an optical image formed by the lens 702 into image data (image signal). The signal processing unit 708 performs various corrections, data compression, and the like on the imaging data output from the imaging device 700. The timing generation unit 720 outputs various timing signals to the imaging device 700 and the signal processing unit 708. The overall control/arithmetic unit 718 controls the entire digital still camera, and the memory unit 710 temporarily stores image data. The recording medium control I/F unit 716 is an interface for recording or reading image data on or from the recording medium 714, and the recording medium 714 is a detachable recording medium such as a semiconductor memory for recording or reading imaging data. The external I/F unit 712 is an interface for communicating with an external computer or the like. The timing signal and the like may be input from the outside of the equipment 7. The equipment 7 may further include a display device (a monitor, an electronic viewfinder, or the like) that displays information obtained by the imaging device 700. The equipment 7 includes at least a photoelectric conversion device. Further, the equipment 7 includes at least one of an optical device, a control device, a processing device, a display device, a storage device, and a mechanical device that operates based on information obtained by the photoelectric conversion device. The mechanical device is a movable unit (for example, a robot arm) that operates by receiving a signal of the photoelectric conversion device.

Each pixel may include a plurality of photoelectric conversion units (a first photoelectric conversion unit and a second photoelectric conversion unit). The signal processing unit 708 may be configured to process the pixel signal based on the charge generated in the first photoelectric conversion unit and the pixel signal based on the charge generated in the second photoelectric conversion unit, and acquire the distance information from the imaging device 700 to the object.

### Seventh Embodiment

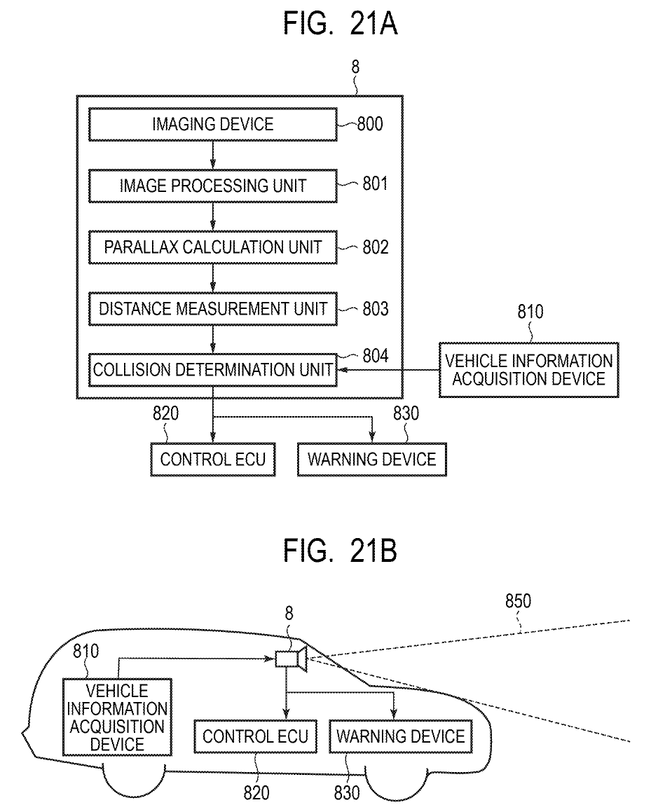

FIGS. 21A and 21B are block diagrams of an equipment 8 related to the in-vehicle camera according to the present embodiment. The equipment 8 includes an imaging device 800 (an example of a photoelectric conversion device) and a signal processing device that processes a signal from the imaging device 800. The equipment 8 includes an image processing unit 801 that performs image processing on a plurality of pieces of image data acquired by the imaging device 800, and a parallax calculation unit 802 that calculates parallax (phase difference of parallax images) from the plurality of pieces of image data acquired by the equipment 8. In addition, the equipment 8 includes a distance measurement unit 803 that calculates a distance to the object based on the calculated parallax, and a collision determination unit 804 that determines whether or not there is a possibility of collision based on the calculated distance. Here, the parallax calculation unit 802 and the distance measurement unit 803 are examples of a distance information acquisition unit that acquires distance information to the object. That is, the distance information is information related to a parallax, a defocus amount, a distance to the object, and the like. The collision determination unit 804 may determine the collision possibility using any of these pieces of distance information. The distance information acquisition unit may be realized by dedicatedly designed hardware or may be realized by a software module. Also, it may be realized by an FPGA (Field Programmable Gate Array), an ASIC (Application Specific Integrated Circuit) or a combination thereof.

The equipment 8 is connected to the vehicle information acquisition device 810, and can acquire vehicle information such as a vehicle speed, a yaw rate, and a steering angle. In addition, a control ECU 820, which is a control device that outputs a control signal for generating a braking force to the vehicle based on the determination result of the collision determination unit 804, is connected to the equipment 8. The equipment 8 is also connected to a warning device 830 that issues a warning to the driver based on the determination result of the collision determination unit 804. For example, when the determination result of the collision determination unit 804 indicates that the possibility of collision is high, the control ECU 820 performs vehicle control to avoid collision and reduce damage by, for example, applying a brake, returning an accelerator, or suppressing engine output. The warning device 830 gives a warning to the user by sounding a warning such as a sound, displaying warning information on a screen of a car navigation system or the like, giving vibration to a seat belt or a steering wheel, or the like. The equipment 8 functions as a control unit that controls the operation of the vehicle as described above.

In the present embodiment, the surroundings of the vehicle, for example, the front or the rear, are imaged by the equipment 8. FIG. 21B illustrates an equipment in a case of capturing an image in front of the vehicle (imaging range 850). The vehicle information acquisition device 810 serving as the imaging control unit sends an instruction to the equipment 8 or the imaging device 800 to perform the imaging operation. With such a configuration, the accuracy of distance measurement can be further improved.

In the above description, an example in which control is performed so as not to collide with another vehicle has been described, but the present disclosure is also applicable to control in which autonomous driving is performed so as to follow another vehicle, control in which autonomous driving is performed so as not to depart from a lane, and the like. Further, the equipment 8 is not limited to a vehicle such as an automobile, and can be applied to, for example, a ship, an aircraft, an artificial satellite, an industrial robot, a consumer robot, or other mobile objects (mobile devices). In addition, the present disclosure is not limited to mobile objects, and can be widely applied to devices utilizing object recognition or biometric recognition, such as an intelligent traffic system (ITS) and a monitoring system.

### Modified Embodiments

The present disclosure is not limited to the above embodiments, and various modifications are possible. For example, an example in which a partial configuration of one embodiment is added to another embodiment or an example in which a partial configuration of one embodiment is replaced with a partial configuration of another embodiment is also an embodiment of the present disclosure.

For example, although an example in which the P-type well region 91 is formed and the NMOS transistors are disposed in the second region 202 has been described, the present disclosure is not limited thereto, and the N-type well region may be formed and the PMOS transistors may be disposed.

One signal processing unit 20 is not necessarily provided for one photoelectric conversion unit 10, and a plurality of photoelectric conversion units 10 may share the signal processing unit 20.

In addition, although the count processing unit 23 is a 4-bit counter, it may be a counter of N (N is 2 or more) bits, for example, a counter of 10 bits or more. In addition, although an asynchronous counter is used, a synchronous counter may be used.

Although an example in which the reset signal pRES is commonly input to each flip-flop 230 has been described, the present disclosure is not limited thereto, and for example, the reset signal pRES may be separately input to the flip-flops 230.

Although an example in which the pixel P does not include a memory circuit that stores the count value from the count processing unit 23 has been described, the present disclosure is not limited thereto and may include a memory circuit.

According to the photoelectric conversion device of the present disclosure, it is possible to suppress an increase in the circuit area including the count processing unit in the pixel.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-083225, filed May 19, 2025, and Japanese Patent Application No. 2026-037722, filed Mar. 10, 2026, which are hereby incorporated by reference herein in their entirety.

What is claimed is:

1. A photoelectric conversion device comprising:
a pixel including a photoelectric conversion element and a count processing unit configured to perform count processing on a signal output from the photoelectric conversion element;
a first substrate on which the photoelectric conversion element is formed; and
a second substrate on which the count processing unit is formed so as to overlap at least a part of the photoelectric conversion element in a plan view, and which is stacked on the first substrate,
wherein the count processing unit includes a plurality of first conductivity type transistors and a plurality of second conductivity type transistors, and
wherein, in the second substrate, the count processing unit is divided into a first region including an equal number of the first conductivity type transistors and the second conductivity type transistors, and a second region including either the first conductivity type transistors or the second conductivity type transistors.

2. The photoelectric conversion device according to claim 1, wherein either a well region of the first conductivity type or a well region of the second conductivity type is formed in the second region.

3. The photoelectric conversion device according to claim 1, wherein the first region and the second region are each rectangular in the plan view.

4. The photoelectric conversion device according to claim 1, wherein the first region and the second region are adjacent to each other.

5. The photoelectric conversion device according to claim 1, wherein the count processing unit includes no surplus region equal to or larger than a size of any of the transistors in the plan view.

6. The photoelectric conversion device according to claim 1,
wherein the count processing unit includes a plurality of flip-flops, and
wherein each of the plurality of flip-flops includes a reset transistor configured to reset a count value of the count processing unit and other transistors other than the reset transistor.

7. The photoelectric conversion device according to claim 6, wherein the first region includes the other transistors, and the second region includes the reset transistor.

8. The photoelectric conversion device according to claim 6, wherein a common reset signal is input to at least two of the reset transistors in the plurality of flip-flops.

9. The photoelectric conversion device according to claim 6,
wherein the plurality of flip-flops are arranged in a matrix in a first direction and a second direction intersecting the first direction in the first region,
wherein the second region is arranged in the first direction with respect to the first region, and
wherein the plurality of reset transistors are arranged side by side in the second direction and are adjacent to each other.

10. The photoelectric conversion device according to claim 9,
wherein the plurality of other transistors are arranged in a matrix in the first direction and the second direction in the first region, and
wherein the number of the other transistors in the second direction is the same as the number of the reset transistors in the second direction.

11. The photoelectric conversion device according to claim 6,
wherein each of the plurality of reset transistors includes a gate electrode to which a reset signal is input, and
wherein the plurality of gate electrodes constitute a common electrode.

12. The photoelectric conversion device according to claim 6,
wherein the plurality of flip-flops are arranged side by side in a first direction in the first region,
wherein the second region is arranged in a second direction intersecting the first direction with respect to the first region, and
wherein the plurality of reset transistors are arranged side by side in the first direction and are adjacent to each other.

13. The photoelectric conversion device according to claim 12,
wherein the pixel includes a selection circuit configured to output a count signal from the count processing unit to the outside of the pixel, and
wherein the selection circuit includes a transistor of the same conductivity type as the reset transistor and is arranged in the second region.

14. The photoelectric conversion device according to claim 13, wherein the transistor of the selection circuit and the reset transistor are adjacent to each other in the second region.

15. The photoelectric conversion device according to claim 13,
wherein the pixel includes a first interconnect connecting the other transistors and the reset transistor, and a second interconnect connecting the count processing unit and the selection circuit, and
wherein the first interconnect and the second interconnect are formed in the same interconnect layer, and each extends in the second direction.

16. The photoelectric conversion device according to claim 15, wherein the other transistors of a first flip-flop and the other transistors of a second flip-flop are arranged in line symmetry with respect to a boundary line between the first flip-flop and the second flip-flop.

17. The photoelectric conversion device according to claim 16, wherein the first interconnect and the second interconnect of the first flip-flop and the first interconnect and the second interconnect of the second flip-flop are arranged in line symmetry with respect to the boundary line.

18. The photoelectric conversion device according to claim 1, wherein the photoelectric conversion element is an avalanche photodiode.

19. The photoelectric conversion device according to claim 18, further comprising a third substrate provided between the first substrate and the second substrate,
wherein the pixel includes a charge circuit configured to apply a reverse bias voltage to the avalanche photodiode, and
wherein the charge circuit is formed on the third substrate.

20. An equipment comprising:
the photoelectric conversion device according to claim 1; and
at least one of
an optical device corresponding to the photoelectric conversion device,
a control device configured to control the photoelectric conversion device,
a processing device configured to process a signal output from the photoelectric conversion device,
a display device configured to display information obtained by the photoelectric conversion device,
a storage device configured to store information obtained by the photoelectric conversion device, and
a mechanical device configured to operate based on information obtained by the photoelectric conversion device.
